(19) United States
(12) Patent Application Publication
(10) Pub. No.: US 2025/0038162 A1
(43) Pub. Date: Jan. 30, 2025

(54) NON-VOLATILE DYNAMIC RANDOM ACCESS MEMORY

(71) Applicant: Adeia Semiconductor Technologies LLC, San Jose, CA (US)

(72) Inventors: Javier A. DeLaCruz, San Jose, CA (US); Pear Po-Yee Cheng, Los Altos, CA (US); David Edward Fisch, Pleasanton, CA (US)

(21) Appl. No.: 18/906,043

(22) Filed: Oct. 3, 2024

Related U.S. Application Data
(63) Continuation of application No. 17/070,253, filed on Oct. 14, 2020, now Pat. No. 12,113,054.
(60) Provisional application No. 62/923,839, filed on Oct. 21, 2019.

(51) Int. Cl. H01L 25/18; H01L 23/00; H01L 25/065

(52) U.S. Cl. CPC H01L 25/18; H01L 24/08; H01L 25/0657; H01L 2224/08145; H01L 2924/1431; H01L 2924/1436; H01L 2924/14511

(57) ABSTRACT

The present disclosure provides for a stacked memory combining RAM and one or more layers of NVM, such as NAND. For example, a first layer of RAM, such as DRAM, is coupled to multiple consecutive layers of NAND using direct bonding interconnect (DBI®). Serialization and overhead that exists in periphery of the NVM may be stripped to manage the data stored therein. The resulting connections between the RAM and the NVM are high bandwidth, high pincount interconnects. Interconnects between each of the one or more layers of NVM are also very dense.

### CROSS-REFERENCE TO RELATED APPLICATIONS

This application is a continuation of U.S. Nonprovisional application Ser. No. 17/070,253, filed Oct. 14, 2020, which claims the benefit of the filing date of U.S. Provisional Patent Application No. 62/923,839, filed Oct. 21, 2019. The disclosure of each of the above applications is hereby incorporated herein by reference in its entirety.

### BACKGROUND

Various types of existing memory each have significant limitations. For example, Dynamic Random Access Memory (DRAM) is fast, but low density and volatile. NAND is dense and inexpensive, but slow. Magnetic RAM (MRAM) is neither dense nor fast, and is also relatively expensive.

While some solutions have sought to combine NAND and DRAM, they are combined at the package level. For example, while some packages have been created that include both a NAND and a DRAM, each of the NAND and DRAM has separate interfaces with input and output. Accordingly, such solutions retain the inefficiencies of the individual memories.

### BRIEF DESCRIPTION OF THE DRAWINGS

FIG. 1 is a side view of an example stacked memory combining RAM and one or more layers of non-volatile memory (NVM) according to aspects of the disclosure.

FIG. 2 is a side view of another example stacked memory combining RAM and one or more layers of NVM according to aspects of the disclosure.

FIG. 3 is a relational diagram of components of the stacked memory according to aspects of the disclosure.

FIGS. 4A-B are example circuit diagrams of example stacks according to aspects of the disclosure.

FIG. 5 is a perspective view of another example stacked memory combining RAM and multiple layers of NVM according to aspects of the disclosure.

FIG. 6 is a top view of an example layer of NVM according to aspects of the disclosure.

FIG. 7 is a side view of another example stacked memory combining RAM and one or more layers of NVM according to aspects of the disclosure.

FIG. 8 is a side view of another example stacked memory combining RAM and one or more layers of NVM according to aspects of the disclosure.

### DETAILED DESCRIPTION OF THE PREFERRED EMBODIMENT

### Overview

The present disclosure provides for a stacked memory combining RAM and one or more layers of NVM, such as NAND. For example, a first layer of RAM, such as DRAM, is coupled to multiple consecutive layers of NAND using direct bonding interconnect (DBI®). Serialization and overhead that exists in periphery of the NVM may be stripped to manage the data stored therein. The resulting connections between the RAM and the NVM are high bandwidth, high pincount interconnects. Interconnects between each layer of NVM are also very dense.

According to some examples, the RAM may store logic for the NVM. In other examples, a separate layer of logic for the NVM may be coupled in the stack between the RAM and the NVM. While including the NVM logic in the DRAM layer may provide for a smaller stack size as compared to including the logic in a separate layer, having a separate non-volatile logic layer frees up more of the RAM for memory.

The RAM may include an interface for receiving data for storage and outputting data from storage. The logic may determine which data is stored in NVM and which data is buffered for RAM storage. According to some examples, data to be stored in the memory stack may be tagged to indicate whether it is for short term storage in the RAM or long term storage in the NVM layers. Just as one example, machine learning may be used to detect whether the data received at an input to the DRAM is intended for short term or long term storage.

DRAM arrays can serve as registers and temporarily hold data loaded from a flash NVM plane and in turn supply this data to the outside world. Multiple registers operating together can allow for proportionally faster uninterrupted I/O speeds. For example, if four registers are used, each associated with a different flash memory array (plane), if the array page load speed is 25 us, a clock speed of 12 ns could be supported. 8 planes could support a read clock speed of 6 ns.

The RAM may also be used in write operations and can accept external data while other RAM arrays are supplying data to the NVM for programming. For example, while the NVM layers are writing data to storage, the RAM layer may continue to receive additional data as input without waiting for the NVM write to complete. Because programming operations are typically longer than page load operations (e.g., ˜300 us/page programming vs. 25 us/page for reads), data can be fully loaded into the RAM arrays before programming operations are complete.

The combined NVM and RAM stack described here may be useful for a variety of different applications, including, for example, machine learning applications. For example, machine learning applications may require weight memory, such as information that has been learned that is needed to perform computation. The weight memory can be a large amount of memory, wherein moving that weight memory burns a large amount of power. However, moving the data over the highly parallel path between the NVM in the stack and the RAM may be done over a short electrical distance, and therefore not burn as much power. Because in a machine learning application it is known ahead of time when the weight memory will be used, the weight memory can be queued and loaded into RAM for faster access. For example, if it is known that the weight memory is used sequentially to multiply accumulate (MAC) operations with activations, access to the weight memory can be queued for faster operation. Moreover, the NVM can automatically write as the RAM is exchanging information with a controller, such as an application specific integrated circuit (ASIC) or system on chip (SoC). At the same time, the NVM can also start reading the next operation.

A process for making the combined NVM and RAM stack may start with a larger layer of NVM. Multiple additional layers of NVM may be bonded thereto, for example, using DBI®. The RAM layer may then be bonded to a bottom-most layer of the NVM. The result resembles a single die that can be stacked on another die, mounted on an interposer, or packaged independently.

### Example Structures

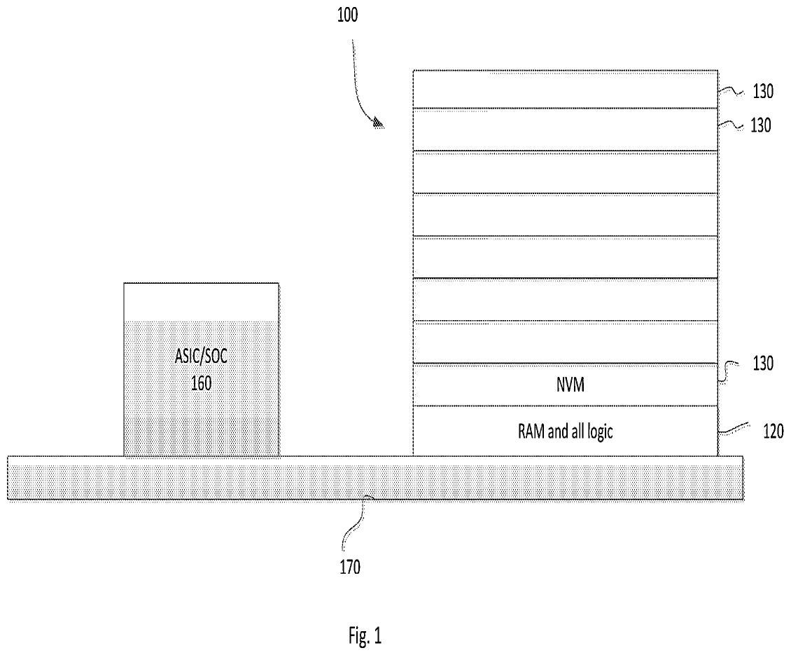

FIG. 1 illustrates a first example of the stacked memory combining RAM and one or more layers of NVM. In particular, stack 100 and controller 160 are positioned on and interconnected by a circuit board or package 170. The controller 160 may be any of variety of types of controllers. For example, the controller may be a system on chip (SoC), application specific integrated circuit (ASIC), or the like. The stack 100 includes a RAM layer 120 at a base of the stack, and a plurality of layers of non-volatile memory (NVM) 130 stacked above the RAM layer 120.

The NVM layers 130 may include any of a variety of types of nonvolatile memory, such as NAND flash memory, NOR flash memory, EPROM, EEPROM, magnetoresitive RAM (MRAM), phase change RAM, etc. Each layer of NVM may be bonded together using, for example, low temperature bonding techniques such as DBI®. Each layer of NVM may be, for example, approximately 50 μm thick or less. While several layers of NVM 130 are shown, it should be understood that any number of NVM layers 130 may be included in the stack. A total thickness of the NVM layers 130 may be, for example, 450 μm or less.

The RAM layer 120 may be dynamic RAM (DRAM), static RAM (SRAM), Synchronous Dynamic RAM (SDRAM), Single Data Rate Synchronous Dynamic RAM (SDR SDRAM), Double Data Rate Synchronous Dynamic RAM (DDR SDRAM, DDR2, DDR3, DDR4), Graphics Double Data Rate Synchronous Dynamic RAM (GDDR SDRAM, GDDR2, GDDR3, GDDR4, GDDR5), NRAM, RRAM, or any of a variety of other types of memory. The RAM layer 120 includes an external interface for communication with the controller 160, the external interface further providing for communication between the NVM layers 130 and the controller 160.

The RAM layer 120 is also interconnected to a bottom layer of NVM in the stack 100. For example, the RAM layer 120 may be bonded using various bonding techniques, including using direct dielectric bonding, non-adhesive techniques, such as a ZiBond® direct bonding technique, or a DBI® hybrid bonding technique, both available from Invensas Bonding Technologies, Inc. (formerly Ziptronix, Inc.), a subsidiary of Xperi Corp. (see for example, U.S. Pat. Nos. 6,864,585 and 7,485,968, which are incorporated herein in their entirety).

According to the example of FIG. 1, logic for the RAM and the NVM layers 130 may all be stored in the RAM layer 120. Integration of the NVM logic into the RAM layer 120 may provide for a smaller physical size of the stack.

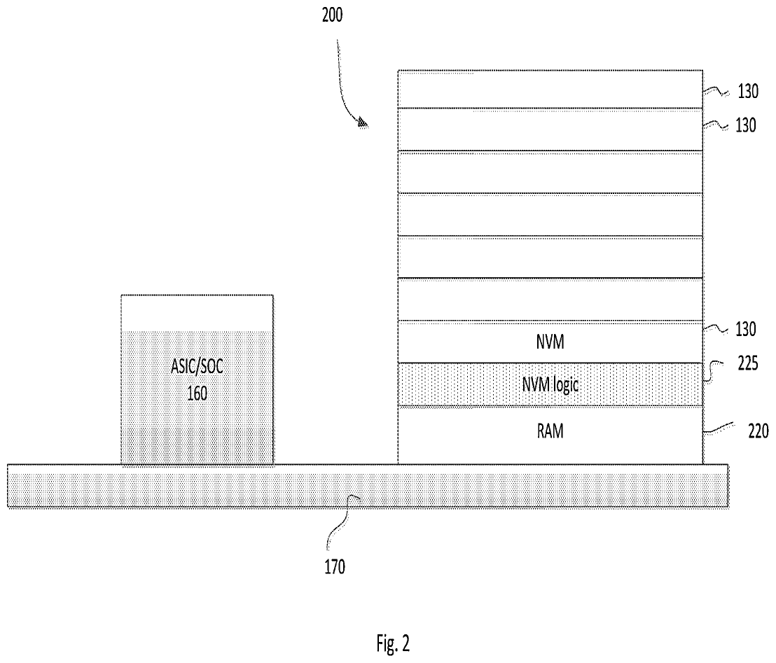

In another embodiment, shown in FIG. 2, logic for the NVM layers 120 may be stored in a separate NVM logic layer 225. In this example, RAM layer 220 may include more memory space as compared to the example of FIG. 1. Additionally, NVM logic layer 225 may be removed and replaced with another NVM logic layer if needed. For example, if additional NVM layers are added, or if updated logic is available, the logic layer 225 may be exchanged for an updated logic layer.

In either embodiment of FIG. 1 or FIG. 2, as the RAM layer 120, 220 receives data for storage, the logic may be used to determine how the data is stored. As one example, the data may be tagged, wherein the tags provide an indication of whether the data should be stored in short term memory or long term memory. For example, the tag may be one or more bits. If the bit is set to 1, for example, the data may be stored in RAM, whereas if the bit is set to 0, the data may be stored in NVM. Data tagging can also have a different bit pattern which will provide the necessary identification to determine the storage location of the data. Just as one example, the tags may identify a type of data, such as whether the data is a lookup table, weight memory, intermediate data, etc. As the data is received, the logic may determine, based on the tag, whether to buffer the data in RAM layer 120 for short term use, or to move the data up the stack to the NVM layers 130 for long term use.

According to one example, if a time to complete a read load, such as moving data from flash cells to a register, is 25 us, and a clock speed is 24 ns, moving 2112 bytes, 2 bytes at a time, will require 1056 clock cycles. 1056 cycles*24 ns/cycle=25.344 us. With this example scenario, if a first register has been filled with data, and has been sending the data out through the I/O's 2 bytes at a time, it will have completed that operation in 25.344 us. While this operation has been in progress, a 2^{nd} register could be loaded from a new NAND flash page and could be ready to start providing its data to other devices outside the stack. The process may continue with the first register getting filled by the flash array while the 2^{nd} register is providing data to other devices outside the stack. This allows a continuous read of data from flash memory. If the array is slower and needs more time to load a page from the flash array to its register, then a slower clock speed would be necessary to avoid dead cycles if ping panging between two registers.

According to some examples, a capacitive layer may also be included in the combined memory stack. For example, a wafer layer may be configured to hold a charge. Just as one example, the wafer layer may include a layer of silicon with collimated pores that is covered with dielectric. The capacitive layer may be at a top of the NVM stack, furthest from system-level connections, stacked between the RAM layer and the NVM layers, or in any other layer. In the event of a power outage, the capacitive layer may provide enough power to finish writing anything remaining in the RAM layer to the NVM layers.

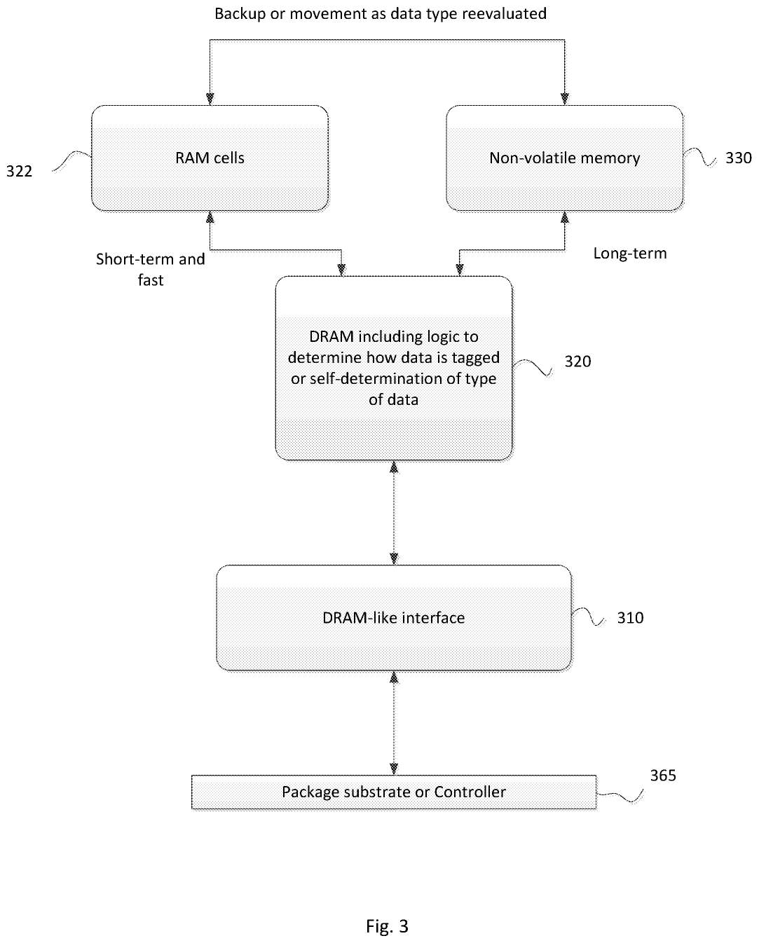

FIG. 3 illustrates an example of data flow for data that is received by the stack for storage, or data being accessed by an external device. DRAM-like interface 310 communicates with external devices, such as package substrate or controller 365. The DRAM-like interface 310 may include, for example, bumps, pads, pillars, DBI, or any other type of interconnect. DRAM-like interface 310 may receive data to be stored in memory, and the DRAM uses logic 320 to determine where the data should be stored. For example, the logic may look at tags on the data to determine whether the data is better suited for long term storage or short term storage. The tags may be assigned by a processor, such as ASIC/SoC 160 of FIG. 2.

In some examples, the logic for determining where the data should be stored may include a machine learning algorithm. For example, data usage may be evaluated. What is learned from the evaluations may be used to better classify data that is received, wherein the classifications determine where the data is stored.

Once it is determined whether the data should be stored in long term or short term storage, the data is moved to NVM 330 or to RAM cells 322, respectively. According to some aspects, the data stored in NVM 330 and/or Ram cells 322 may be reevaluated from time to time, and moved based on the reevaluation. For example, if a first set of data stored in NVM 330 is accessed more frequently than a second set of data stored in RAM 322, the first set of data may be moved to RAM 322 and/or the second set of data may be moved to NVM 330. As another example, if the RAM 322 is becoming full, some of the data stored therein may be moved to NVM 330.

Similar to the way in which the data is moved up from the external device through the layers of the memory stack to store the data, data may be accessed by communications through the DRAM-like interface 310. Further, data may be moved down the stack and transmitted out to external devices through the DRAM-like interface 310.

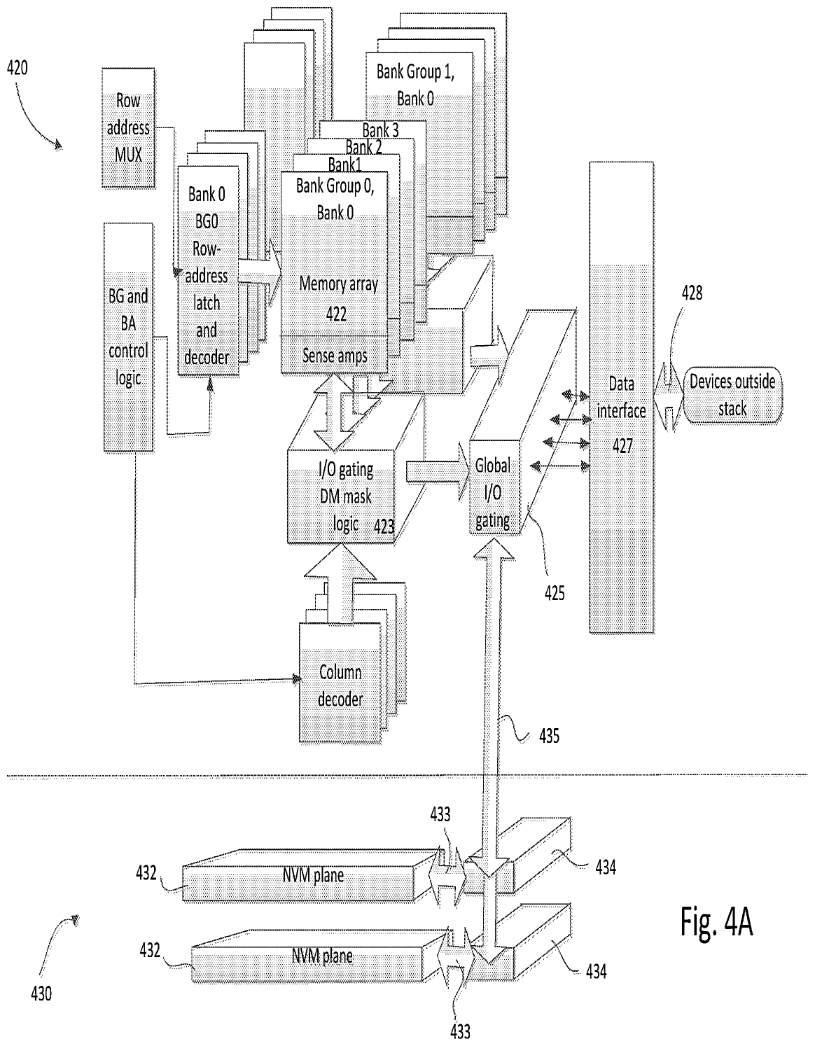

An I/O path between the RAM layer and the NVM layers may be relatively wide. For example, as described in further detail below in connection with FIGS. 4-6, a layer of NVM may include multiple planes, with each plane having multiple memory blocks and each memory block configured to store multiple pages of data. The RAM may be configured such that it can load an entire page simultaneously to the NVM. Speeds of write/read operations may be increased to increase the speed to the NVM. Such pipelining frees up RAM capacity for subsequent operations more quickly.

FIG. 4A illustrates a first example circuit structure for the RAM-NVM stack. As shown, volatile memory (VM) portion 420 is coupled to an NVM portion 430 including stacked layers of NVM.

The VM portion 420 may be a layer of RAM, such as DRAM or other type of RAM. The VM portion 420 may include a memory array 422 including a plurality of memory banks. According to some examples, the memory array 422 may include multiple groups of memory, with each group having multiple memory banks. Each memory bank may include a plurality of sense amplifiers for use when reading data from the memory. The sense amplifiers may be coupled to a global I/O gate 425, such as through I/O gating mask logic 423. The global I/O gate may further be coupled to a data interface 427 for sending or receiving communications between the RAM portion 420 and other devices outside of the stack. For example, a bus 428 between the data interface 427 and off-chip devices can be any bus width, such as 4, 8, 16, 32, 64, 128 bits wide, etc. If an internal bus width is increased, the bus 428 width may also be increased.

The NVM portion 430 includes multiple NVM planes 432 or arrays, each NVM plane 432 being coupled to NVM sense amplifiers and drivers 434 through NVM array bus 433. The NVM array bus 433 may be, for example, 16,384 bits wide with optional error correction bits. The sense amplifiers and drivers 434 are further coupled to the global I/O gating 425 through bus 435. For example, the bus 435 may be any width, such as 128 bits or wider. In some examples, the bus 435 may be 1 k bit wide, 16 k bit wide, or greater.

FIG. 4B illustrates another example including the VM portion 420 and the NVM portion 430. In this example, however, the sense amplifiers and drivers 434 of the NVM portion 430 are directly coupled to the sense amplifiers of the memory array 422 in the VM portion 420. For example, a first bus 435a may couple first sense amplifiers and drivers 434a to the sense amplifiers of the first group of the memory array 422. Similarly, a second bus 435b may couple second sense amplifiers and drivers 434b to the sense amplifiers of the second group of the memory array 422. While only two groups of memory arrays are shown, and two NVM planes, it should be understood that multiple additional memory array groups and NVM planes may be included.

According to some examples, rather than sending data in page sizes, the data may be sent in error correction code (ECC) chunks. For example, ECC information in a NAND page may be matched an ECC interval in a DRAM page.

Each layer of NAND in the NAND flash array plane may include extra bits. In this regard, the DRAM may overprovision data to be stored in the NAND, such that more bits are available than those advertised. In this regard, if a NAND location is starting to fail because it is being written to too often, the data can be redirected to a different set of cells in NAND.

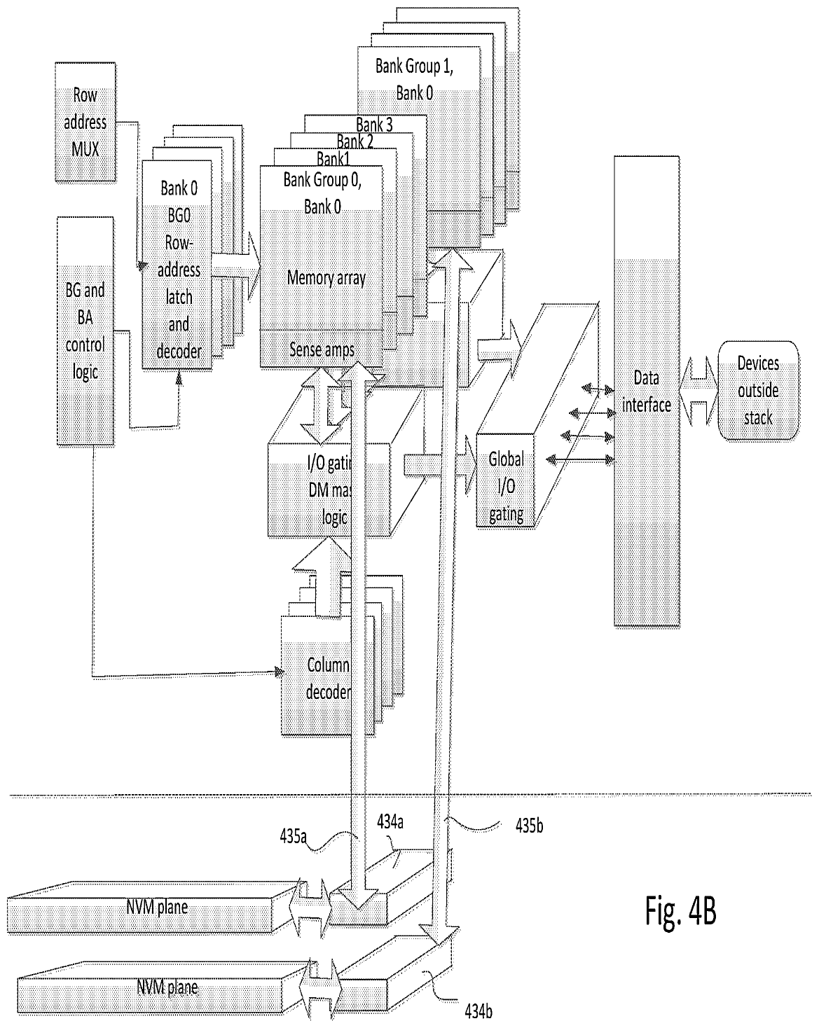

FIG. 5 is a perspective view of another example stacked memory combining RAM and NVM. In this example, RAM 520 is a larger width than each of a plurality of NVM array planes 540 coupled thereto. Each array plane 540 has a register and multiple memory blocks of flash memory. The RAM 520 may be mounted over and connected to the plurality of flash array planes 540. For example, the RAM can be directly connected to a flash page (as shown), or it can be directly connected to a register. The RAM may be bonded to the flash page using low temperature bonding, hybrid bonding, or other types of bonding.

The RAM 520 is capable of outputting or inputting data fast enough to give a continuous pipeline of data. For example, data stored in the RAM may be retrieved in 25 μs or less. As another example, the NVM is capable of providing in parallel a page of M bits of data with a cycle time T1. The RAM memory locations can capture and store a page content within a time T2 that is less than or equal to the read cycle time T1 of the corresponding NVM flash page. According to some examples, the RAM 520 memory chip may be connected in total to N output nodes and each output node can provide a new bit of data in a time T3 that is equal to or less than T1*N/(M*P), wherein P is a number of the NVM array planes 540. The stacked memory may be capable of providing a continuous stream of output data at a data rate=1/T3. In other examples, the data rate may be greater than 1/T3/1.25. By way of example only, if a page is 16,896 bits, and there are 2-8 NVM array planes 540, the total number of output nodes N to which the RAM chip may be connected=8-16.

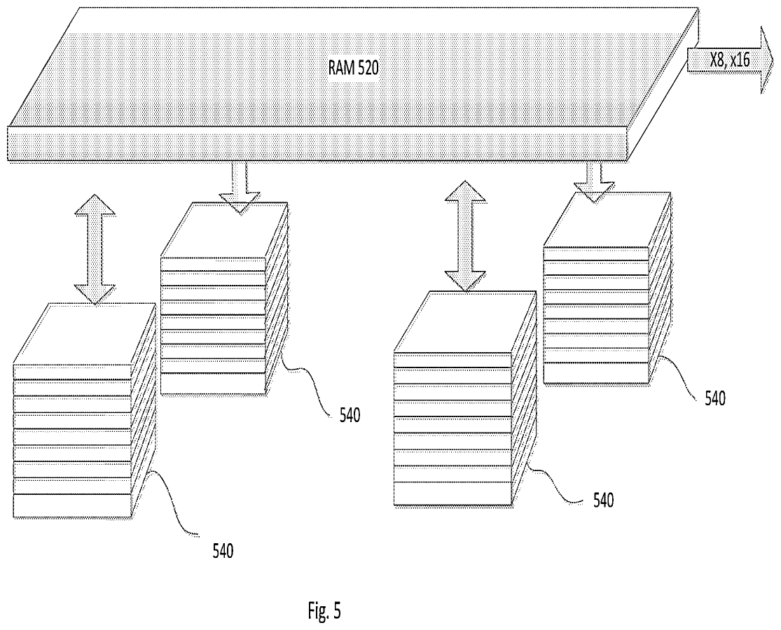

FIG. 6 is a top view of an example layer of NVM. Each block 604 includes a plurality of pages 602. Each page 606 includes a plurality of blocks 604. Die 608 may include a plurality of pages 606. Above each plane 606 is a register (not shown) that can capture data in one of more of the pages 602. While here two pages 606 are shown, it should be understood that in other examples the die may include more pages. Similarly, while a number of block 604 and pages 602 are shown, it should be understood that the number may be varied.

Each plane 606 may operate independently. Accordingly, while a first plane of the die 608 is writing data, a second plane of the same die 608 may be reading a next operation from RAM.

According to some examples, in addition to being coupled to a first type of NVM, the RAM may also be coupled to other types of NVM, such as embedded NVM (ENVM). For example, the NVM and ENVM may share a same layer of the stack, such as if the NVM and ENVM are positioned alongside one another. As another example, the ENVM may be a separate layer of the stack from the NVM.

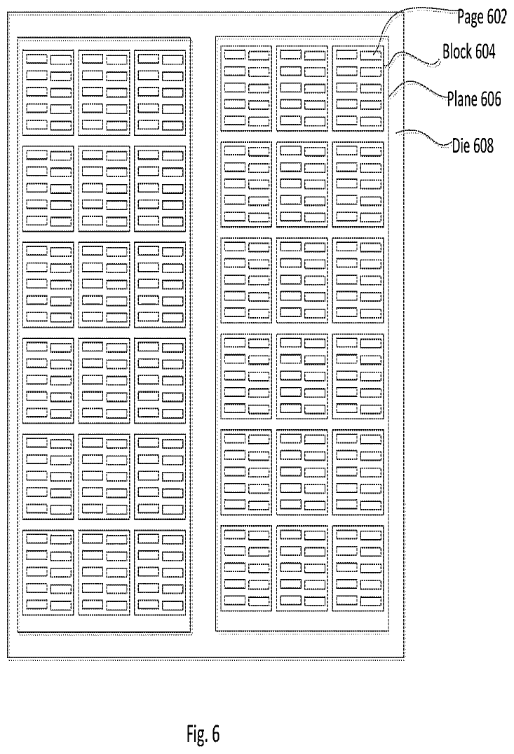

FIG. 7 illustrates an example of the ENVM and the NVM sharing a layer of the stack. In this example, NVM 730 and ENVM 735 are positioned adjacent one another on a same layer 738 of the stack, above RAM 720. Though not shown, additional NVM layers may be stacked above the shared layer 738. Between the shared RAM 720 and the shared layer 738 is a logic layer 725. This logic layer 725 may be accessed by the RAM, for example, to determine whether to store data in short term or long term storage. Further, if the data is to be stored in long term storage, the logic may be accessed to determine whether to store the data using the NVM 730 or the ENVM 735. In this regard, the NVM 730 and the ENVM 735 may share the logic layer 725.

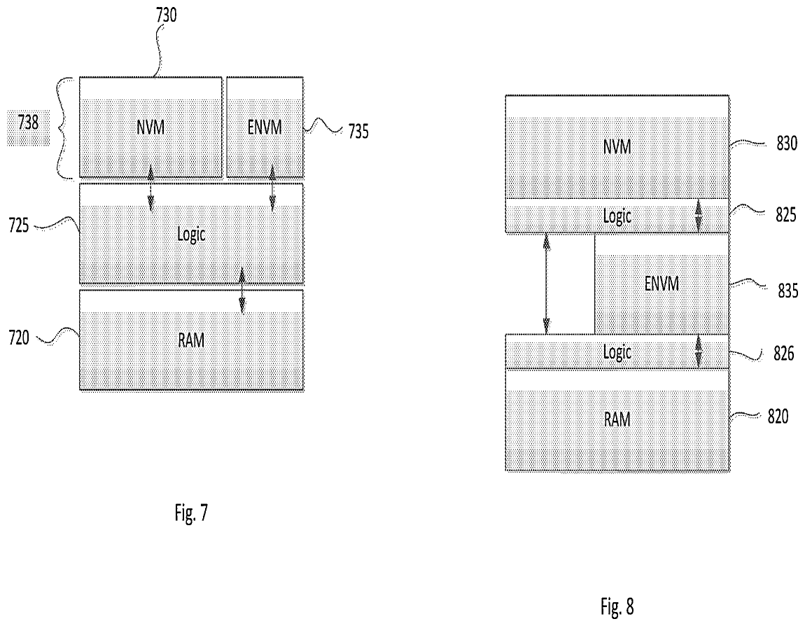

FIG. 8 illustrates an example where the ENVM and NVM occupy different layers of the stack. In this example, ENVM 835 resides in its own dedicated layer in the stack between RAM 820 and NVM 830. Though not shown, additional NVM layers may be stacked above the NVM 830. The NVM 830 and the ENVM 835 may each have a logic layer 825, 826, respectively. The NVM 830 may communicate with the ENVM 835 through logic layer 825. The ENVM 835 may communicate with the RAM 820 through logic layer 826. While in some examples, the NVM 830 may communicate with the RAM 820 through the ENVM 835 and intervening logic layers 825, 826, in other examples the NVM 830 may communicate directly with the RAM 820 via a direct connection between the logic layers 825, 826. For example, any of a number of signal routing mechanisms may be used to form the connection, such as routing layers, hard-wired connection, pillars, etc. The ENVM 835 does not need to be a same physical size as each NVM die or wafer in the stack. For example, the ENVM 835 may occupy a space that is physically smaller than a space occupied by a layer of NVM 830, such as if a NVM wafer is bonded to an ENVM die.

While some examples of integrating ENVM have been described above, it should be understood that additional examples are possible. For example, ENVM may be stack between layers of NVM, logic for the ENVM may reside on the RAM, etc.

### Example Applications

The combined RAM and NVM memory stack as described in the examples above may be used for storing data for any of a variety of applications. Just as one example, the stack may be used in machine learning applications, where weight memory is stored in the NVM layers and activations are stored in RAM. As weights and activations are input to and stored in the stack, multiply accumulate (MAC) operations may be output. The weight memory may be moved to RAM over the highly parallel path between the NVM in the stack and the RAM. Because this path is a short electrical distance, power consumption is relatively low. Moreover, such movement can be scheduled. For example, it may be determined that a first operation is always or often followed by a second operation that requires accessing the weight memory. In this regard, the weight memory may be queued into RAM each time the first operation is performed, without waiting for the second operation. Additionally, the NVM can concurrently write as the RAM is exchanging information with a controller, such as an application specific integrated circuit (ASIC) or system on chip (SoC). At the same time, the NVM can also start reading the next operation. Because different pins may be used for reading and writing at a given time, the RAM may continuously be supplied with data to store in NVM while also sending data off-chip. Each of the different pins may be bidirectional, and many different buses may be available. While the RAM is communicating with the controller, it is reading data or sending data. At the same time, internally, it could be moving data to the NVM.

Other example applications may include switching. For example, a layer of NVM may be reserved for a lookup table. Further example applications include high-performance compute applications, mobile devices, etc.

Although the invention herein has been described with reference to particular embodiments, it is to be understood that these embodiments are merely illustrative of the principles and applications of the present invention. It is therefore to be understood that numerous modifications may be made to the illustrative embodiments and that other arrangements may be devised without departing from the spirit and scope of the present invention as defined by the appended claims.

What is claimed is:

1. An integrated circuit (IC) device, comprising:
a processor and a memory die stack communicatively coupled to each other and disposed laterally adjacent to each other on a common substrate; and
the memory die stack comprising a plurality of dies vertically stacked on top of one another, the dies comprising a random access memory (RAM) die and a nonvolatile memory (NVM) die,
wherein interconnects of the RAM die are directly bonded to interconnects of the NVM die without an intervening material layer therebetween.

2. The IC device of claim 1, wherein the memory die stack is communicatively coupled to receive data from the processor through the common substrate, wherein the memory die stack comprises logic for determining whether the data is to be stored in the RAM die or the NVM die.

3. The IC device of claim 2, wherein the logic determines whether the data is to be stored in the RAM die or the NVM die based on a tag assigned by the processor.

4. The IC device of claim 2, wherein the logic determines whether the data is to be stored in the RAM die or the NVM die based on classification performed using a machine learning algorithm.

5. The IC device of claim 2, wherein the logic is integrated as part of the RAM die.

6. The IC device of claim 2, wherein the logic is separately integrated from the RAM die.

7. The IC device of claim 1, wherein the memory die stack comprises a plurality of NVM dies stacked on top of the RAM die.

8. The IC device of claim 1, wherein the directly bonded interconnects form a plurality of parallel input/output (I/O) paths between the RAM die and the NVM die, wherein the parallel I/O paths are at least 1 k bits wide.

9. The IC device of claim 1, wherein one or more of the dies are directly hybrid bonded to one another.

10. The IC device of claim 1, wherein the common substrate comprises an interposer.

11. The IC device of claim 1, wherein the processor comprises one or more of a system on chip (SoC) and an application specific integrated circuit (ASIC).

12. An integrated circuit (IC) device, comprising:
a processor and a memory die stack disposed laterally adjacent to each other on a common substrate; and
the memory die stack comprising a plurality of dies vertically stacked on top of one another, the dies comprising a random access memory (RAM) die and a nonvolatile memory (NVM) die vertically stacked on top of one another,
wherein a bottommost die of the memory die stack comprises an interface circuitry through which the processor and the memory die stack are communicatively coupled to each other.

13. The IC device of claim 12, wherein the bottommost die is the RAM die.

14. The IC device of claim 12, wherein the bottommost die further comprises logic for determining whether data received from the processor is to be stored in the RAM die or the NVM die.

15. The IC device of claim 14, wherein the logic is integrated as part of the RAM die.

16. The IC device of claim 14, wherein the logic is separately integrated from the RAM die.

17. The IC device of claim 12, wherein one or more dies are directly hybrid bonded to one another.

18. The IC device of claim 12, wherein the common substrate comprises an interposer.

19. The IC device of claim 12, wherein the memory die stack comprises a plurality of NVM dies stacked on top of the RAM die.
